(19) United States
(12) Patent Application Publication
(10) Pub. No.: US 2013/0040456 A1
(43) Pub. Date: Feb. 14, 2013

(54) METHOD OF MANUFACTURING SEMICONDUCTOR DEVICE

(71) Applicants: Hajime EDA, Yokohama-shi (JP); Yukiteru Matsui, Yokohama-shi (JP); Gaku Minamihaba, Yokohama-shi (JP); Akifumi Gawase, Yokohama-shi (JP)

(72) Inventors: Hajime EDA, Yokohama-shi (JP); Yukiteru Matsui, Yokohama-shi (JP); Gaku Minamihaba, Yokohama-shi (JP); Akifumi Gawase, Yokohama-shi (JP)

(21) Appl. No.: 13/427,950

(22) Filed: Mar. 23, 2012

(30) Foreign Application Priority Data
Aug. 12, 2011 (JP) 2011-177208

(51) Int. Cl. H01L 21/768

(52) U.S. Cl. 438/653; 257/E21.584

(57) ABSTRACT

According to one embodiment, a method of manufacturing a semiconductor device is provided. In the method, a groove is formed in a insulating film on a semiconductor substrate. An underlayer film is formed on the insulating film. A metal film is formed on the underlayer film. First polishing, in which the metal film is removed, is performed by supplying a first CMP slurry containing metal ions. The surfaces of the polishing pad and the semiconductor substrate are cleaned by supplying organic acid and pure water. Second polishing, in which the underlayer film is removed from the portion other than the groove, is performed by supplying a second CMP slurry different from the first CMP slurry.

### CROSS-REFERENCE TO RELATED APPLICATIONS

This application is based upon and claims the benefit of priority from prior Japanese Patent Application No. 2011-177208, filed Aug. 12, 2011, the entire contents of which are incorporated herein by reference.

### FIELD

Embodiments described herein relate generally to a method of manufacturing a semiconductor device.

### BACKGROUND

In recent years, Chemical Mechanical Polishing (CMP) has often been used as a process of planarizing surfaces in the process of forming multilayer wiring and element isolation in semiconductor devices. In particular, a planarizing process in a multilayer wiring includes two CMP processes: CMP (metal CMP) of a metal film that is to be a wiring; and CMP (barrier metal CMP) of an underlayer film formed on a surface of the wiring. Usually, the two CMP processes are performed discontinuously. That is, the two CMP processes are performed in different chambers (on different polishing pads) in a CMP device.

Reasons for performing the metal CMP and the barrier metal CMP discontinuously include difference in slurry configuration used between the metal CMP and the barrier metal CMP and decrease in stability of polishing characteristics due to increase in amount of polishing time as a result of continuous processing.

For example, in metal CMP where W is used as a metal film, a slurry is used that provides a higher polishing rate with respect to W than SiO₂, which is used as an inter-wiring insulating film. In this case, the ratio of polishing rates of SiO₂ to W obtained by the slurry should desirably be 1 to 10 or greater. For that reason, an oxidant is generally added to the slurry, in order to enhance the polishing rate of W. In some cases, the slurry is designed to contain Fe ions as a catalyst, in order to increase the oxidizing power of the oxidant.

In barrier metal CMP, on the other hand, a slurry is often designed to have an alkaline pH level in order to obtain practical polishing rates with respect to W and SiO₂, and to attain a balance between the polishing rates of W and SiO₂. In order to suppress the polishing rate of W, an oxidant with a reduced oxidizing power or an antioxidant is generally added to the slurry.

From the viewpoint of productivity, proposals have been made to perform metal CMP and barrier metal CMP continuously (i.e., perform the two processes in the same chamber). When the slurries used in metal CMP and barrier metal CMP that are performed continuously have opposite liquid properties, however, the active components of the slurries often cancel each other out. Further, due to flocculation of abrasive grains, desired polishing characteristics cannot be obtained. Even if the liquid properties of the slurries used in metal CMP and barrier metal CMP are the same, that is, the slurries fall into the same pH category and contain similar components, an oxidant or a catalyst with a strong oxidizing power contained in the slurry used in metal CMP remains on the surface of the pad even in barrier metal CMP, thereby varying the polishing rate.

Further, since the residual amount of the components of the slurry varies according to the polishing conditions and the condition of the pad, stable polishing characteristics cannot be obtained. Moreover, since the two kinds of CMP processes are performed continuously, the coefficient of elasticity of the pad varies as the amount of time of continuous polishing increases. This in turn causes the polishing characteristics of the subsequent barrier metal CMP process to vary greatly.

Thus, when the two CMP processes are performed continuously, the polishing characteristics deteriorate compared to when the processes are performed discontinuously. An effective approach to this problem involved in continuous processing of the CMP processes is to use slurries with a higher similarity in components in metal CMP and barrier metal CMP. Due to limitations in increasing similarity of the slurries used in the two CMP processes, however, it is difficult in continuous processing to obtain polishing characteristics at a level equal to that of the polishing characteristics of discontinuous processing.

### BRIEF DESCRIPTION OF THE DRAWINGS

FIG. 1 is a cross-sectional view illustrating a manufacturing process of a wiring configuration of a semiconductor device according to the present embodiment;

FIG. 2 is a cross-sectional view illustrating a wiring configuration after CMP;

FIG. 3 is a plane view illustrating a CMP device according to the present embodiment;

FIG. 4 illustrates a configuration of a first polishing unit shown in FIG. 3;

FIG. 5 illustrates a configuration of a first roll cleaning unit shown in FIG. 3;

FIG. 6 illustrates a configuration of a first pencil cleaning unit shown in FIG. 3;

FIG. 7 is a flowchart illustrating a comparative example of a CMP method according to the present embodiment;

FIG. 8 is a flowchart illustrating the CMP method according to the present embodiment;

FIG. 9 schematically shows chemical solution processing of the CMP method according to the present embodiment;

FIG. 10 illustrates a chemical reaction of the chemical solution processing of the CMP method according to the present embodiment;

FIG. 11 is a graph illustrating smoothness of the wiring in the CMP method according to the present embodiment and a comparative example thereof;

FIG. 12 is a graph illustrating the number of defects in the CMP method according to the present embodiment and a comparative example thereof;

FIG. 13 is a graph illustrating a polishing rate of a slurry used in first polishing in the CMP method according to the present embodiment; and

FIG. 14 is a graph illustrating temperature dependence of a coefficient of elasticity of a polishing pad in the CMP device according to the present embodiment.

### DETAILED DESCRIPTION

In general, according to one embodiment, a method of manufacturing a semiconductor device is provided. In the method, an insulating film is formed on a surface of a semiconductor substrate. A groove is formed in the insulating film. An underlayer film is formed on the insulating film. A metal film is formed on the underlayer film so as to fill in the groove. By making the surface of the semiconductor substrate contact with a rotating polishing pad and supplying a first CMP slurry containing metal ions to a surface of the polishing pad, first polishing is performed, in which the metal film is removed from a portion other than the groove. By making the surface of the semiconductor substrate contact with the polishing pad and supplying organic acid and pure water to the surface of the polishing pad, the surfaces of the polishing pad and the semiconductor substrate are cleaned. By making the surface of the semiconductor substrate contact with the polishing pad and supplying a second CMP slurry different from the first CMP slurry to the surface of the polishing pad, second polishing is performed, in which the underlayer film is removed from the portion other than the groove.

Hereinafter, the present embodiment will be described with reference to the accompanying drawings. In the descriptions that follow, the same structural elements will be denoted by the same reference numerals. Further, redundant descriptions will be made only when necessary.

### Embodiment

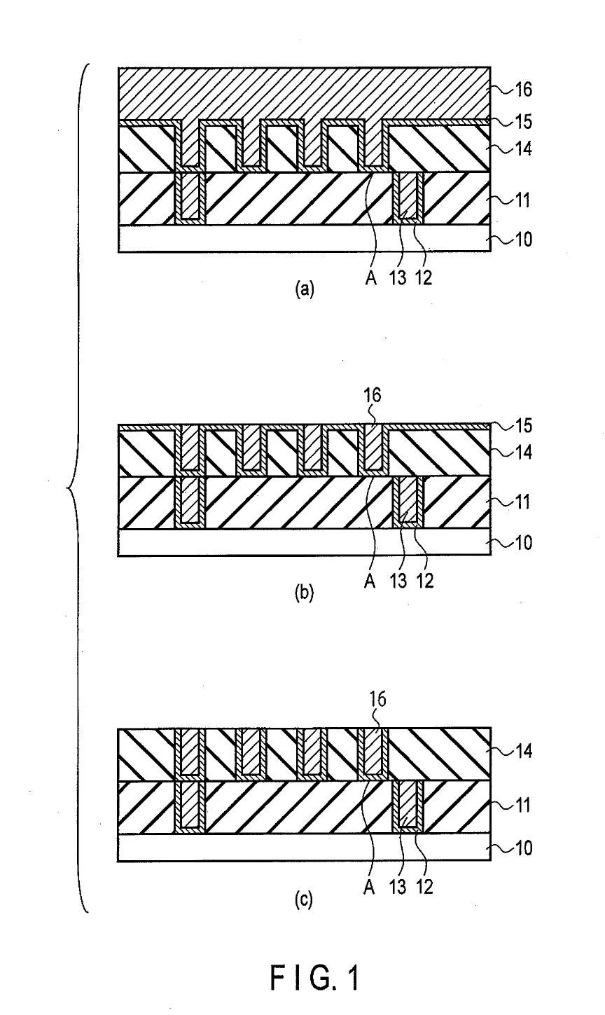

A method of manufacturing a semiconductor device according to the present embodiment will be described with reference to FIGS. 1, 2, 3, 4, 5, 6, 7, 8, 9, 10, 11, 12, 13, and 14. The method of manufacturing a semiconductor device according to the present embodiment relates to a CMP process in a manufacturing process of a wiring configuration, in which metal CMP and barrier metal (BM) CMP are performed continuously in the same chamber. Thereby, productivity is improved. In this method, surfaces of a polishing pad and a semiconductor substrate are cleaned with organic acid after the metal CMP. Thereby, since the components included in the slurry used in the metal CMP and varying the polishing rate of the subsequent barrier metal CMP is removed, it is possible to suppress deterioration in polishing characteristics involved in continuous processing. Hereinafter, the method of manufacturing a semiconductor device according to the embodiment will be described.

[Method of Manufacturing Wiring Configuration]

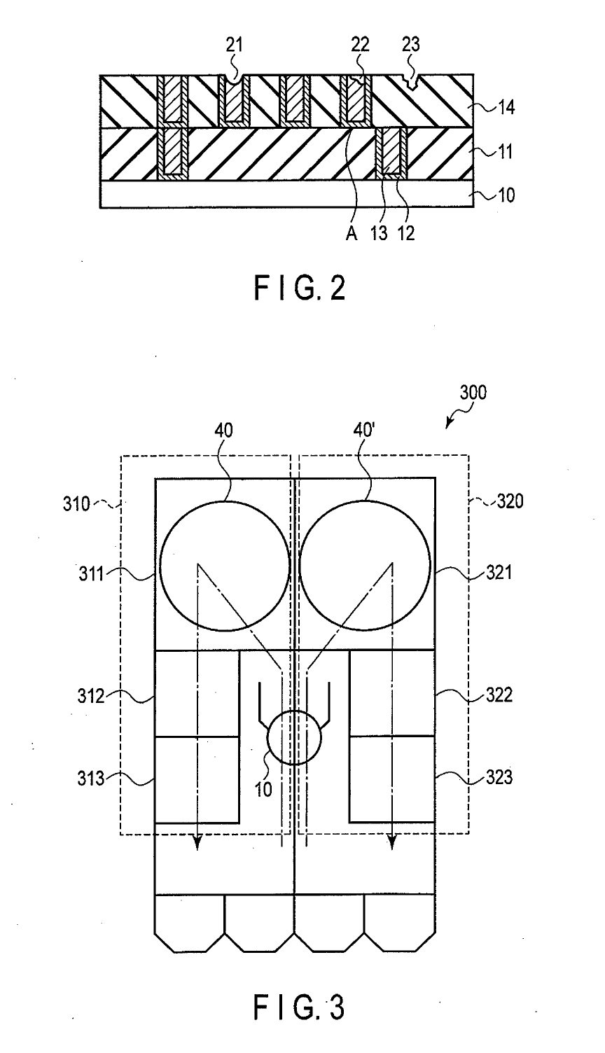

A manufacturing process of a wiring configuration of the semiconductor device according to the present embodiment will be described with reference to FIGS. 1 and 2.

FIG. 1 is a cross-sectional view illustrating a manufacturing process of a wiring configuration of the semiconductor device according to the present embodiment. FIG. 2 is a cross-sectional view illustrating a wiring configuration after CMP.

As shown in FIG. 1 (a), an insulating film 11 is formed on a semiconductor substrate 10, on which a semiconductor device (not shown) is formed. The insulating film 11 is formed of SiO₂, for example. A contact hole is formed in the insulating film 11, and a contact plug 13 is formed in the contact hole via a barrier metal 12. The barrier metal 12 is formed of Ti or Ta, or a nitride thereof, for example, and the contact plug 13 is formed of W, for example. Thereby, a contact layer is formed which includes the insulating film 11, the barrier metal 12, and the contact plug 13.

After that, an insulating film 14 is formed on the contact layer. The insulating film 14 is formed of SiO₂, for example. A wiring groove A is formed in the insulating film 14 as a concave portion. The wiring groove A is formed as a wiring having a coverage of 50%, for example.

After that, a barrier metal 15, which is to be an underlayer film of the wiring, is formed on the entire surface, using a conventional technique (such as CVD). That is, the barrier metal 15 is formed in the wiring groove A and on a portion of the insulating film 14 other than the wiring groove 14. The barrier metal 15 is formed of Ti or Ta, or a nitride thereof, for example.

After that, a metal film 16, which is to be a wiring, is formed on the entire surface so as to fill in the wiring groove A, using a conventional technique (such as CVD). That is, the metal film 16 is formed in the wiring groove A and on a portion of the barrier metal 15 other than the wiring groove A. The metal film 16 is formed of W or Cu, for example.

After that, CMP is performed on the entire surface. In this CMP process, first polishing (metal CMP) and second polishing (barrier metal CMP) are performed. The second polishing is also referred to as touch-up.

More specifically, as shown in FIG. 1 (b), an excess part of the metal layer 16 formed on the portion other than the wiring groove A is removed in the first polishing. Thereby, the metal film 16 is embedded in the wiring groove A. In the portion other than the wiring groove A, the surface of the barrier metal 15 is exposed. That is, the metal film 16 (formed of W or Cu, for example) is the main target film in the first polishing.

After that, as shown in FIG. 1 (c), the barrier metal 15 is removed from the portion other than the wiring groove A in the second polishing. Thereby, the surface of the insulating film 14 is exposed in the portion other than the wiring groove A. In the second polishing, a part of the surface of the insulating film 14 is also removed in order to fully remove the metal film 16 and the barrier metal 15. That is, the metal film 16 (formed of W or Cu, for example), the barrier metal 15 (formed of Ti or Ta, or a nitride thereof, for example), and the insulating film 14 (formed of SiO₂, for example) are the main target films in the second polishing. Thereby, a wiring layer is formed which includes the insulating film 14, the barrier metal 15, and the metal film 16. Details of the CMP according to the present embodiment will be described later.

As shown in FIG. 2, dishing 21 and erosion 22 are generated in the metal film 16 after the CMP process. Further, a defect 23 is generated in the insulating film 14. These can cause the wiring characteristics to deteriorate.

When the first polishing process and the second polishing process are performed on the same turntable continuously, the polishing characteristics usually deteriorate compared to when the two processes are performed on different turntables discontinuously. Accordingly, the dishing 21, the erosion 22, and the defect 23 increase in continuous processing.

The present embodiment provides an example of CMP in which deterioration of the polishing characteristics is suppressed while performing the first polishing and the second polishing continuously.

[CMP Device]

A CMP device 300 according to the present embodiment will be described with reference to FIG. 3, 4, 5, 6. In this case, FREX300X from Ebara Corporation is used as the CMP device 300 by way of illustration.

FIG. 3 is a plane view illustrating the CMP device 300 according to the present embodiment.

As shown in FIG. 3, the CMP device 300 comprises a first CMP unit 310 and a second CMP unit 320.

The first CMP unit 310 includes a first polishing unit 311, a first roll cleaning unit 312, and a first pencil cleaning unit 313. The semiconductor substrate 10 (target film) is conveyed to the first polishing unit 311, the first roll cleaning unit 312, and the first pencil cleaning unit 313 in this order by a conveyor unit, not shown. That is, after the semiconductor substrate 10 is polished in the first polishing unit 311, the semiconductor substrate 10 is subjected to roll cleaning in the first roll cleaning unit 312, and then subjected to pencil cleaning in the first pencil cleaning unit 313. Hereinafter, a detailed description will be given on each of the units.

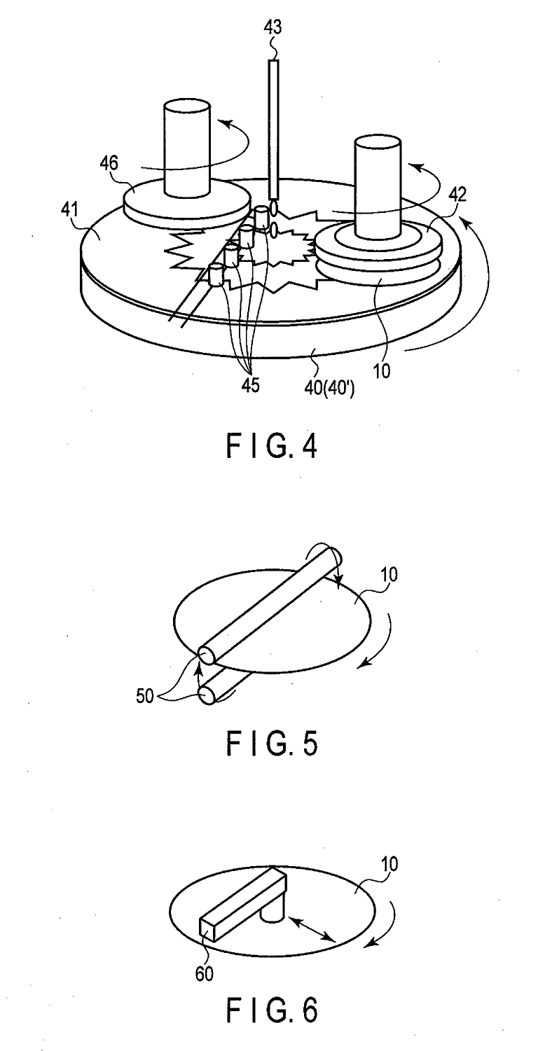

FIG. 4 illustrates a configuration of the first polishing unit 311 shown in FIG. 3.

As shown in FIG. 4, a turntable 40, on a surface of which a polishing pad 41 is affixed, is provided in the first polishing unit 311.

The semiconductor substrate 10 (target film) is made to contact with the polishing pad 41 affixed on the turntable 40 during polishing of the target film. The turntable 40 is rotatable at 1-200 rpm, and a top ring 42 is rotatable at 1-200 rpm. The turntable 40 and the top ring 42 rotate in a counterclockwise direction, for example. During polishing, the turntable 40 and the top ring 42 rotate in a certain direction. The polishing loads are usually 50-500 hPa, but are not limited thereto and may be adjusted as appropriate.

A slurry supply nozzle 43 is provided on the polishing pad 41. From the slurry supply nozzle 43, a predetermined chemical solution can be supplied as a slurry at a flow rate of 50-500 cc/min.

On the polishing pad 41, there is provided a cooling nozzle 45 which ejects a compressed air or a nitride gas, for example, toward the polishing pad 41. The cooling nozzle 45 ejects the compressed air toward the polishing pad 41 approximately in the range of 0-1000 l/min, thereby controling the temperature of the surface of the polishing pad 41 during polishing.

FIG. 4 also shows a dresser 46 provided on the polishing pad 41. After polishing of the target film is finished, the dresser 46 rotates at 1-200 rpm and is made to contact with the polishing pad 41 under a load of 50-500 hPa. Thereby, the dresser 46 performs conditioning of the surface of the polishing pad 41.

FIG. 5 shows a configuration of the first roll cleaning unit 312 shown in FIG. 3.

As shown in FIG. 5, a roll brush 50, designed to perform roll cleaning, is provided in the first roll cleaning unit 312.

In roll cleaning of the target film, the roll brush 50 is provided on each of the top surface (target film side) and the back surface of the semiconductor substrate 10. The roll brush 50 has a length equal to the diameter of the semiconductor substrate 10, and is provided on the diameter of the semiconductor substrate 10. The roll brush 50 is cylindrical in shape and is designed to clean the both surfaces of the semiconductor substrate 10 by rotating about the central axis of the cylinder. At this, time, the semiconductor substrate 10 is held by a holder, not shown, and rotates in a certain direction. Through the roll cleaning, the semiconductor substrate 10 is physically cleaned by the roll brush 50, and is also chemically cleaned by being supplied with a chemical solution. The roll cleaning is performed more roughly than the subsequent pencil cleaning.

FIG. 6 shows a configuration of the first pencil cleaning unit 313 shown in FIG. 3.

As shown in FIG. 6, a pencil brush 60, designed to perform pencil cleaning, is provided in the first pencil cleaning unit 313.

In pencil cleaning of the target film, the pencil brush 60 is provided on the surface of the semiconductor substrate 10 (target film). The pencil brush 60 cleans the surface of the semiconductor substrate 10 by laterally moving on the semiconductor substrate 10. At this time, the semiconductor substrate 10 is held by a holder, not shown, and rotates in a certain direction. Through the pencil cleaning, the semiconductor substrate 10 is physically cleaned by the pencil brush 60, and is also chemically cleaned by being supplied with a chemical solution. The pencil cleaning is performed more finely than the previous roll cleaning.

After the pencil cleaning, the semiconductor substrate 10 is dried out in the first pencil cleaning unit 313.

The second CMP unit 320 includes a second polishing unit 321, a second roll cleaning unit 322, and a second pencil, cleaning unit 323. After processing in the first CMP unit 310 is finished, the semiconductor substrate 10 (target film) is conveyed to the second polishing unit 321, the second roll cleaning unit 322, and the second pencil cleaning unit 323 by a conveyor unit, not shown.

The second cleaning unit 321, the second roll cleaning unit 322, and the second pencil cleaning unit 323 in the second CMP unit 320 have configurations similar to those of the first cleaning unit 311, the first roll cleaning unit 312, and the first pencil cleaning unit 313 in the first CMP unit 310, respectively.

As shown in FIG. 3, however, a turntable 40′ different from the turntable 40 of the first polishing unit 311 is provided in the second polishing unit 321. Accordingly, in the second CMP unit 320, a CMP process different from that of the first CMP unit 310 can be performed on the target film. In addition to that, the first CMP unit 310 and the second CMP unit 320 can perform CMP processes on different semiconductor substrates 10 simultaneously.

[CMP Method]

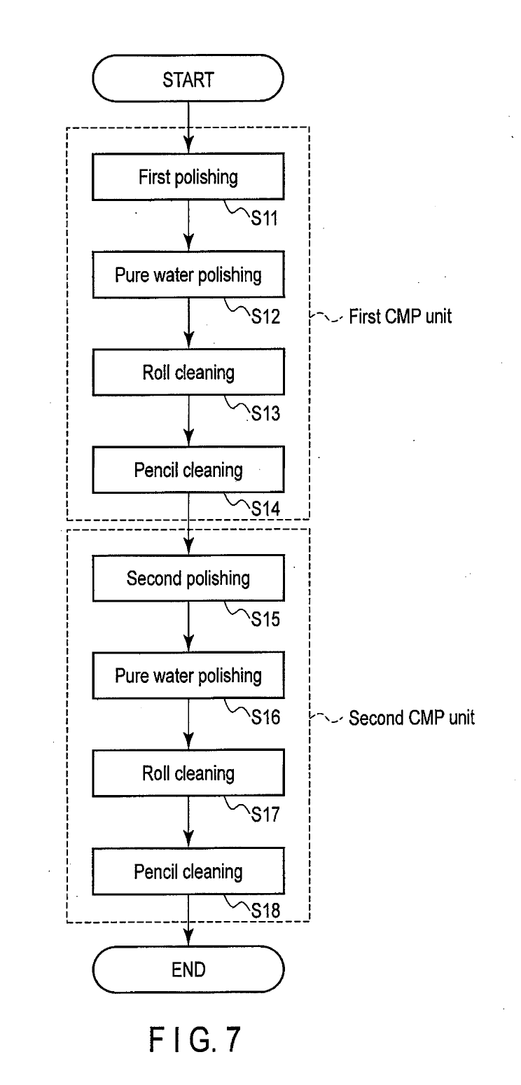

A CMP method according to the present embodiment and a comparative example thereof will be described with reference to FIG. 7, 8, 9, 10. In the description that follows, a CMP method will be described in which W is formed as the metal film 16 in the wiring configuration, but the configuration of the metal film 16 is not limited thereto.

FIG. 7 is a flowchart illustrating a comparative example of the CMP method according to the present embodiment.

As shown in FIG. 7, according to the comparative example, first polishing is performed on a target film in step S11. The first polishing is performed in a first polishing unit 311 after a semiconductor substrate 10 is conveyed to the first polishing unit 311. In the first polishing, a metal film 16 (W) shown in FIG. 1 is mainly polished as the target film. Accordingly, a silica slurry (W7573B) from Cabot Corporation, for example, is used as a slurry supplied to a polishing pad 41. The slurry (first CMP slurry) used in the first polishing contains an oxidant, an additive, an abrasive (silica), and Fe as a catalyst, and has a high polishing rate with respect to W. Examples of preferable oxidants include ammonium persulfate and hydrogen peroxide solution.

After that, in step S12, supply of the slurry is stopped, and pure water polishing (pure water cleaning) is performed on the polishing pad 41 and the target film (semiconductor substrate 10) by supplying pure water. The pure water polishing is performed in the first polishing unit 311 as in the first polishing. The pure water polishing removes a chemical solution and the like on the surfaces of the polishing pad 41 and the target film, without polishing the target film.

After that, in step S13, roll cleaning is performed on the target film (semiconductor substrate 10). The roll cleaning after the first polishing is performed in a first roll cleaning unit 312 after the semiconductor substrate 10 is conveyed from the first polishing unit 311 to the first roll cleaning unit 312. Through the roll cleaning, the semiconductor substrate 10 is physically cleaned by the roll brush 50 and is also chemically cleaned by being supplied with a chemical solution.

After that, in step S14, pencil cleaning is performed on the target film (semiconductor substrate 10). The pencil cleaning after the first polishing is performed in a first pencil cleaning unit 313 after the semiconductor substrate 10 is conveyed from the first roll cleaning unit 312 to the first pencil cleaning unit 313. Through the pencil cleaning, the semiconductor substrate 10 is physically cleaned by the pencil brush 60 and is also chemically cleaned by being supplied with a chemical solution. Through the roll cleaning and the pencil cleaning, foreign substances (such as the chemical solution of the slurry) generated by the first polishing on the surface of the semiconductor substrate 10 are removed.

After that, the semiconductor substrate 10 is dried out, and the moisture content on the surface of the semiconductor substrate 10 is removed. The dry-out is performed in the first pencil cleaning unit 313, as in the pencil cleaning.

Thus, the first polishing process, in which the metal film 16 is the target film, and the subsequent cleaning process (roll cleaning and pencil cleaning after the first polishing) are performed in the first CMP unit 310.

After that, in step S15, second polishing (touch-up) is performed on the target film. The second polishing is performed in a second polishing unit 321 after the semiconductor substrate 10 is conveyed to the second polishing unit 321. In the second polishing, the metal film 16 (W), the barrier metal 15, and the insulating film 14 (SiO₂) shown in FIG. 1 are mainly polished as the target films. Accordingly, a silica slurry (W7203) from Cabot Corporation, for example, is used as a slurry supplied to the polishing pad 41. The slurry (second CMP slurry) used in the second polishing contains an oxidant and an abrasive (silica), and has approximately equal polishing rates with respect to the metal film 16 (W), the barrier metal 15, and the insulating film 14 (SiO₂). Desirably, the polishing rate on the metal film 16 (W) should be lower than the polishing rates on the barrier metal 15 and the insulating film 14 (SiO₂). Examples of preferable oxidants include ammonium persulfate and hydrogen peroxide solution.

After that, in step S16, supply of the slurry is stopped, and pure water polishing is performed on the polishing pad 41 and the target film by supplying pure water. The pure water polishing is performed in the second polishing unit 321 as in the second polishing. The pure water polishing removes a chemical solution and the like on the surfaces of the polishing pad 41 and the target film, without polishing the target film.

After that, in step S17, roll cleaning is performed on the target film (semiconductor substrate 10). The roll cleaning after the second polishing is performed in a second roll cleaning unit 322 after the semiconductor substrate 10 is conveyed from the second polishing unit 321 to the second roll cleaning unit 322. Through the roll cleaning, the semiconductor substrate 10 is physically cleaned by the roll brush 50 and is also chemically cleaned by being supplied with a chemical solution.

After that, in step S18, pencil cleaning is performed on the target film (semiconductor substrate 10). The pencil cleaning after the second polishing is performed in a second pencil cleaning unit 323 after the semiconductor substrate 10 is conveyed from the second roll cleaning unit 322 to the second pencil cleaning unit 323. Through the pencil cleaning, the semiconductor substrate 10 is physically cleaned by the pencil brush 60 and is also chemically cleaned by being supplied with a chemical solution. Through the roll cleaning and the pencil cleaning, foreign substances (such as the chemical solution of the slurry) generated by the second polishing on the surface of the semiconductor substrate 10 are removed.

After that, the semiconductor substrate 10 is dried out, and the moisture content on the surface of the semiconductor substrate 10 is removed. The dry-out is performed in the second pencil cleaning unit 323, as in the pencil cleaning.

Thus, the second polishing process, in which the metal film 16, the barrier metal film 15, and the insulating film 14 are the target films, and the subsequent cleaning process (roll cleaning and pencil cleaning after the second polishing) are performed in the second CMP unit 320.

As described above, according to the comparative example, after the slurry components on the surface of the target film are removed by performing two-step cleaning (roll cleaning and pencil cleaning) after the first polishing, second polishing is performed in a polishing unit (turntable) different from that of the first polishing. That is, the first polishing and the second polishing are performed discontinuously. In discontinuous processing as described above, however, the amount of time of CMP increases due to the two-step cleaning and conveyance of the semiconductor substrate 10 between the units. Further, since two CMP units (the first CMP unit 310 and the second CMP unit 320) are required in order to perform CMP on one semiconductor substrate 10, a problem arises in productivity.

Compared to discontinuous processing, when the first polishing and the second polishing are performed continuously in the same polishing unit, polishing characteristics deteriorate. This is caused by the slurry components of the first polishing remaining on the surfaces of the polishing pad 40 and the target film in the second polishing due to inadequate cleaning, since roll cleaning and pencil cleaning are not performed after the first polishing in continuous processing. In particular, Fe ions contained in the slurry used in the first polishing increases the polishing rate of W, which forms the metal film 16. Accordingly, the polishing rate on the metal film 16 increases in the second polishing too, which results in deterioration in polishing characteristics.

In view of the above, the present embodiment provides a CMP method which suppresses deterioration in polishing characteristics while performing the first polishing and the second polishing continuously.

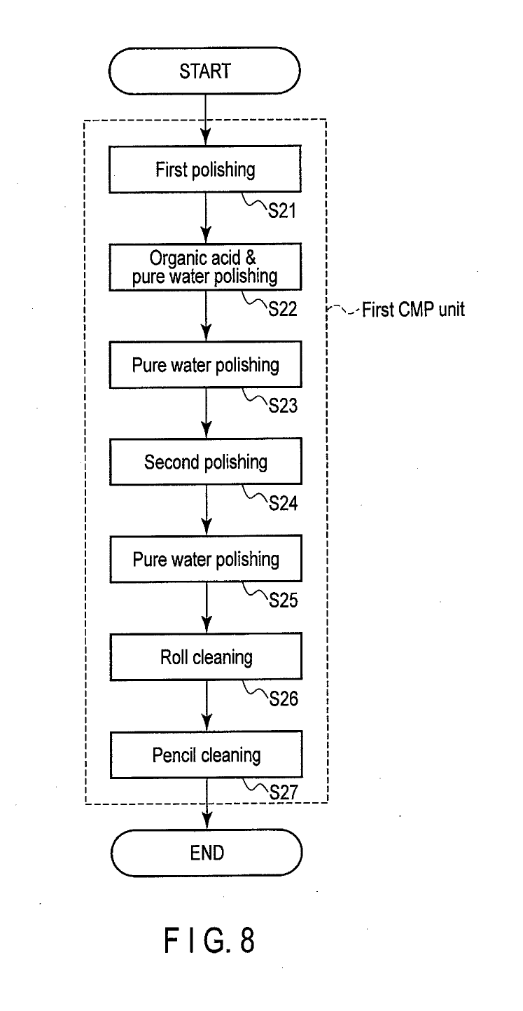

FIG. 8 is a flowchart illustrating the CMP method according to the present embodiment.

As shown in FIG. 8, according to the present embodiment, first polishing is performed on the target film in step S21. The first polishing is performed in the first polishing unit 311 after the semiconductor substrate 10 is conveyed to the first polishing unit 311. In the first polishing, the metal film 16 (W) shown in FIG. 1 is mainly polished as the target film. Accordingly, a silica slurry (W7573B) from Cabot Corporation, for example, is used as a slurry supplied to the polishing pad 41. The slurry (first CMP slurry) used in the first polishing contains an oxidant, an additive, an abrasive (silica), and Fe as a catalyst, and has a high polishing rate with respect to W. Examples of preferable oxidants include ammonium persulfate and hydrogen peroxide solution.

The first polishing is performed as the temperature of the surface of the polishing pad 41 is controlled by adjusting the cooling nozzle 45 and the polishing load between the polishing pad 41 and the target film. More specifically, during the first polishing, the temperature of the surface of the polishing pad 41 is controlled so as to be constant, at temperatures approximately between 30 and 65° C. Thereby, the first polishing can be performed without varying the characteristics (such as the coefficient of elasticity) of the polishing pad 41. The first polishing may also be performed at a desired temperature at which the polishing rate on the target film becomes high.

After that, in step S22, supply of the slurry is stopped, and organic acid and pure water polishing (organic acid and pure water cleaning) is performed on the polishing pad 41 and the target film by supplying organic acid and pure water (organic acid solution). The organic acid and pure water polishing is performed in the first polishing unit 311 as in the first polishing. The organic acid and pure water polishing removes slurry components used in the first polishing from the surfaces of the polishing pad 41 and the target film. In the organic acid and pure water polishing, the target film is not polished. Details about the organic acid and pure water polishing will be described later.

After that, in step S23, supply of the organic acid is stopped, and pure water cleaning is performed on the polishing pad 41 and the target film by supplying only pure water. The pure water cleaning is performed in the first polishing unit 311, as in the first polishing. In the pure water polishing, a chemical solution (such as organic acid) on the surfaces of the polishing pad 41 and the target film is removed without polishing the target film. This suppresses an influence on the polishing rate due to organic acid remaining in the subsequent second polishing process.

After that, in step S24, second polishing (touch-up) is performed on the target film. The second polishing is performed in the first polishing unit 311, as in the first polishing. In the second polishing, the metal film 16 (W), the barrier metal 15, and the insulating film 14 (SiO₂) shown in FIG. 1 are mainly polished as the target films. Accordingly, a silica slurry (W7203) from Cabot Corporation, for example, is used as a slurry supplied to the polishing pad 41. The slurry (second CMP slurry) used in the second polishing contains an oxidant and an abrasive (silica), and has approximately equal polishing rates with respect to the metal film 16 (W), the barrier metal 15, and the insulating film 14 (SiO₂). Desirably, the polishing rate on the metal film 16 (W) should be lower than the polishing rates on the barrier metal 15 and the insulating film 14 (SiO₂). Compared to the first CMP slurry, the second CMP slurry has high polishing rates on the barrier metal 15 and the insulating film 14. Examples of preferable oxidants include ammonium persulfate and hydrogen peroxide solution.

As in the first polishing, the organic acid and pure water polishing, the pure water polishing, and the second polishing are performed as the temperature of the surface of the polishing pad 41 is controlled by adjusting the cooling nozzle 45 and the polishing load between the polishing pad 41 and the target film. More specifically, from the first polishing process through the second polishing process, the target film is polished so as to make the temperature of the surface of the polishing pad 41 constant. Thereby, these processes are performed stably, without varying the characteristics of the polishing pad 41.

After that, in step S25, supply of the slurry is stopped, and pure water polishing is performed on the polishing pad 41 and the target film by supplying pure water. The pure water polishing is performed in the first polishing unit 311, as in the first polishing. In the pure water polishing, a chemical solution and the like on the surfaces of the polishing pad 41 and the target film is removed without polishing the target film.

After that, in step S26, roll cleaning is performed on the target film (semiconductor substrate 10). The roll cleaning is performed in a first roll cleaning unit 312 after the semiconductor substrate 10 is conveyed from the first polishing unit 311 to the first roll cleaning unit 312. Through the roll cleaning, the semiconductor substrate 10 is physically cleaned by the roll brush 50 and is also chemically cleaned by being supplied with a chemical solution.

After that, in step S27, pencil cleaning is performed on the target film (semiconductor substrate 10). The pencil cleaning is performed in a first pencil cleaning unit 313 after the semiconductor substrate 10 is conveyed from the first roll cleaning unit 312 to the first pencil cleaning unit 313. Through the pencil cleaning, the semiconductor substrate 10 is physically cleaned by the pencil brush 60 and is also chemically cleaned by being supplied with a chemical solution. Through the roll cleaning and the pencil cleaning, foreign substances (such as the chemical solution of the slurry) generated by the second polishing on the surface of the semiconductor substrate 10 are removed.

After that, the semiconductor substrate 10 is dried out, and the moisture content on the surface of the semiconductor substrate 10 is removed. The dry-out is performed in the first pencil cleaning unit 313, as in the pencil cleaning.

As described above, in the CMP of the present embodiment, the first polishing and the second polishing are performed continuously in the first CMP unit 310. Further, after the first polishing, cleaning is performed on the polishing pad 41 and the target film, using organic acid. Principles of cleaning using organic acid will be described in detail below.

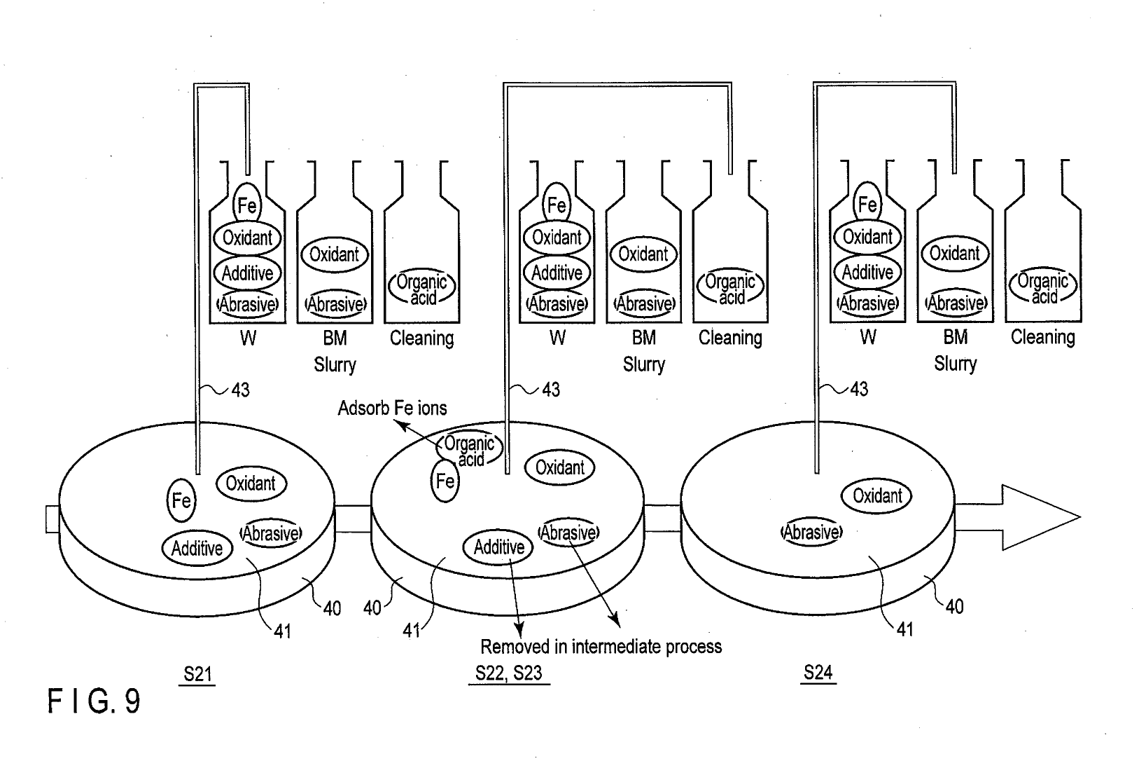

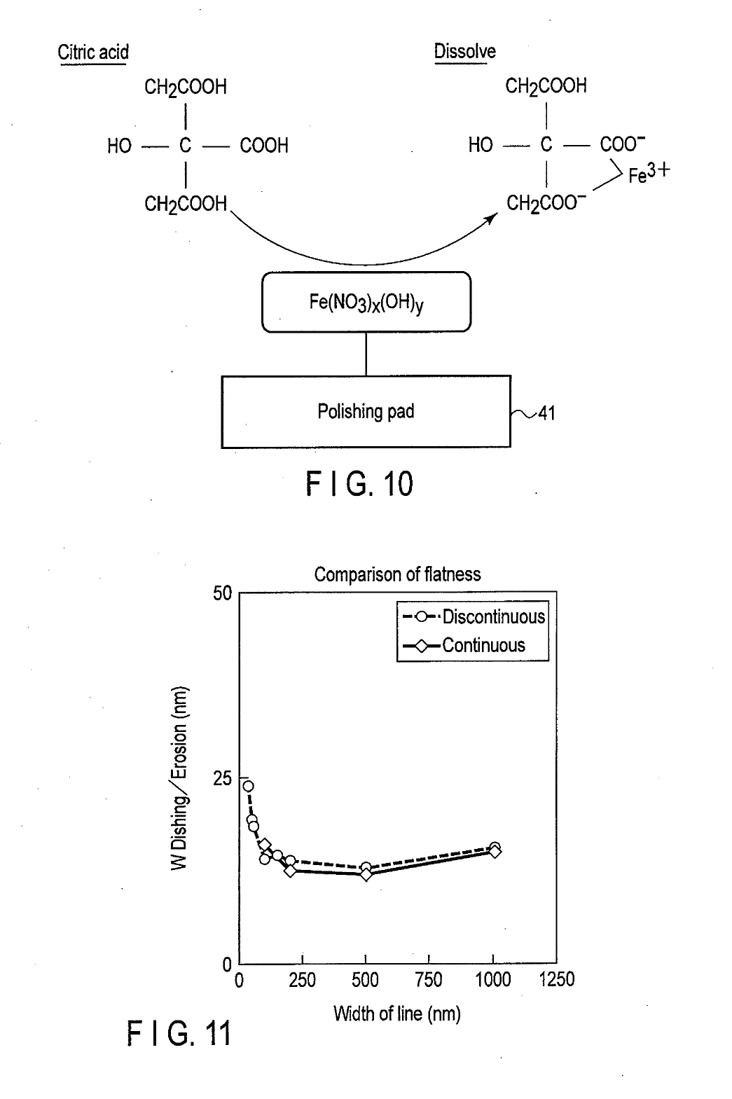

FIG. 9 schematically shows a chemical solution process of the CMP method according to the present embodiment. FIG. 10 shows a chemical reaction of the chemical solution process of the CMP method according to the present embodiment. In the description that follows, a case will be described where W is used as the metal film 16, which is to be the target film.

As shown in FIG. 9, in the first polishing (step S21), a slurry (first CMP slurry) for the metal film 16 is supplied to the surface of the polishing pad 41 by the slurry supply nozzle 43. The slurry for the metal film 16 contains an oxidant, an additive, an abrasive (silica), and Fe as a catalyst. In the first polishing, the metal film 16 is the target film, and Fe, which is one of the slurry components and serves as a catalyst, works to increase the polishing rate on the metal film 16. After the first polishing is finished, the slurry components remain on the surfaces of the polishing pad 41 and the target film.

After that, in the organic acid and pure water polishing (step S22), an organic acid solution (organic acid and pure water) is supplied to the surface of the polishing pad 41 by the slurry supply nozzle 43. The organic acid solution contains for example citric acid as organic acid. The citric acid has two or more ligands. That is, as shown in FIG. 10, by supplying citric acid to the surface of the polishing pad 41, Fe ions on the surfaces of the polishing pad 41 and the target film react with the citric acid to form a complex compound (chelate compound). The chelate compound is soluble in water and is therefore dissolved in the pure water and removed. That is, the remaining Fe ions form a chelate compound with the citric acid and are dissolved in the pure water and removed, by being supplied with citric acid and pure water. The remaining additive and abrasive are removed by pure water or the like.

After that, in the second polishing (step S24), a slurry for the barrier metal 15 (second CMP slurry) is supplied to the surface of the polishing pad 41 by the slurry supply nozzle 43. The slurry for the barrier metal 15 contains an oxidant and an abrasive (silica). In the second polishing, the metal film 16, the barrier metal 15, and the insulating film 14 are the target films, and the slurry for the barrier metal 15 has approximately equal polishing rates on the metal film 16, the barrier metal 15, and the insulating film 14. In the second polishing, since Fe does not remain on the surface of the polishing pad 41 or the target film, it is possible to suppress variation in polishing rate.

In the present embodiment, the organic acid has been described as citric acid as an example, but is not limited thereto. Any organic acid that reacts with the metal ions as a catalyst contained in the first CMP slurry to form a chelate compound may be used, such as malic acid. Further, the catalyst of the first CMP slurry is not limited to Fe but may be Cu. Moreover, the present embodiment is applicable even when the metal film 16, which is the target film, is formed not of W but of Cu.

### ADVANTAGEOUS EFFECT

According to the above-described embodiment, in the CMP process, the first polishing (metal CMP) and the second polishing (barrier metal CMP) are performed continuously in the same chamber (same CMP unit, such as the first CMP unit 310) in the CMP device 300. Thereby, the number of times of conveyance between the units in the CMP device 300 can be reduced, and the amount of time of CMP can be reduced.

Further, a CMP process on one semiconductor wafer (semiconductor substrate 10) can be performed in one of the CMP units (such as the first CMP unit 310). Accordingly, a CMP process can be performed on another semiconductor wafer simultaneously using the other CMP unit (such as the second CMP unit 320). Thereby, productivity is improved.

Further, according to the present embodiment, by cleaning the surfaces of the polishing pad 41 and the target film using organic acid after the first polishing, the slurry components of the first polishing are removed. It is thereby possible to suppress deterioration in polishing characteristics, which is caused by the slurry components of the first polishing remaining in the second polishing. In other words, it is possible to suppress deterioration in polishing characteristics, which is caused by performing the first polishing and the second polishing continuously in the same chamber. The polishing characteristics according to the CMP method of the present embodiment will be described below. The results of examination and the like that will be described below were obtained under the following conditions:

CMP device: FREX300X from Ebara Corporation

Polishing pad: Foaming pad (IC1000) from Nitta Haas Incorporated

First polishing slurry: Silica slurry (W7573B) from Cabot Corporation

Second polishing slurry: Silica slurry (W7203) from Cabot Corporation

Organic acid: Organic acid solution (CLEAN-100) from Wako Pure Chemical Industries, Ltd.

Method of cooling polishing pad: High-pressure air injection

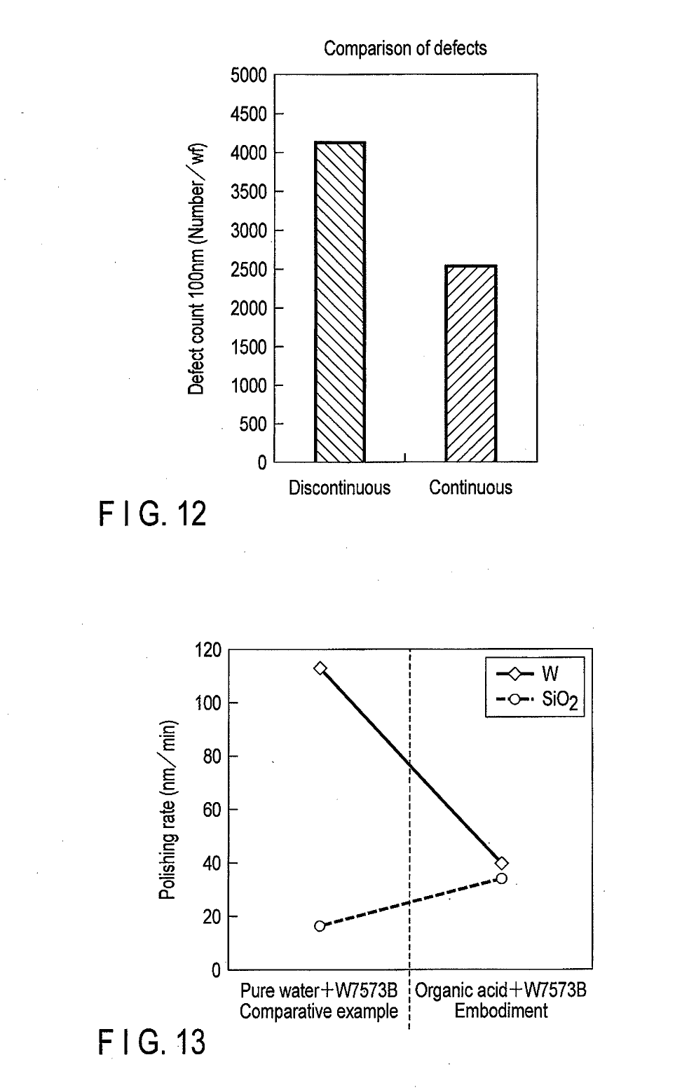

FIG. 11 is a graph illustrating flatness (flatness of the dishing 21 and the erosion 22 of the metal film 16) of the wiring according to the CMP method of the present embodiment and a comparative example thereof. FIG. 12 is a graph illustrating the number of defects (the number of defects 23 in the insulating film 14) according to the CMP method of the present embodiment and a comparative example thereof. More specifically, FIGS. 11 and 12 illustrate an example (present embodiment) in which the first polishing and the second polishing are continuously performed in the same chamber and cleaning is performed after the first polishing using organic acid and an example (comparative example) in which the first polishing and the second polishing are performed discontinuously in different chambers.

As shown in FIG. 11, flatness of the wiring of continuous processing (present embodiment) and flatness of the wiring of discontinuous processing (comparative example) are approximately equal. This is attributed to a decrease in polishing rate of the metal film 16 in the second polishing as a result of Fe ions being removed by organic acid cleaning after the first polishing. That is, by making the polishing rate on the metal film 16 approximately equal to the polishing rates on the barrier metal 15 and the insulating film 14, the dishing 21 and the erosion 22 of the metal film 16 can be reduced. Thus, according to the present embodiment, deterioration in flatness can be suppressed even when CMP is performed continuously, and flatness approximately equal to that of the discontinuous CMP can be obtained.

As shown in FIG. 12, the number of defects in continuous processing (present embodiment) is smaller than the number of defects in discontinuous processing (comparative example). The defect 23 is generated after both of the first polishing and the second polishing. When a drying process (dry-out) is performed after the defect 23 is generated, it becomes difficult to remove the defect 23 thereafter.

In the CMP method of discontinuous processing, a drying process (dry-out) is performed after each of the first polishing and the second polishing. That is, since it is difficult to remove the defect 23 generated in the first polishing and the defect 23 generated in the second polishing thereafter, both of the defects 23 remain.

In the CMP method of continuous processing, on the other hand, the second polishing is performed, without dry-out being performed, after the organic acid and pure water polishing and the pure water polishing are performed in a wet state after the first polishing. That is, the second polishing is performed in a wet state on the defect 23 generated in the first polishing. Accordingly, the defect 23 generated in the first polishing can be removed in the second polishing. That is, in continuous processing, the defect 23 is generated mainly in the second polishing. This leads to a conclusion that the number of defects in continuous processing is smaller than the number of defects in discontinuous processing.

FIG. 13 is a graph illustrating the polishing rate of the slurry used in the first polishing according to the CMP method of the present embodiment. More specifically, FIG. 13 illustrates the polishing rates of W and SiO₂ in a case (present embodiment) where organic acid is added to the slurry (W7573B) used in the first polishing, and the polishing rates of W and SiO₂ in a case (comparative example) where pure water is added.

As shown in FIG. 13, when polishing is performed by adding pure water to the slurry (W7573B) used in the first polishing, the polishing rate of W is higher than the polishing rate of SiO₂. This is attributed to a decrease in oxidizing power of W as a result of reaction between the catalytic component (such as Fe) existing in the slurry and the organic acid.

When polishing is performed by adding organic acid to the slurry (W7573B) used in the first polishing, the polishing rate of W decreases. This is attributed to a decrease in oxidizing power of W as a result of reaction between the catalytic component existing in the slurry and the organic acid. That is, by adding organic acid, it is possible to suppress the catalytic effect that increases the polishing rate of W.

When polishing is performed by adding organic acid to the slurry (W7573B) used in the first polishing, the polishing rate of SiO₂ increases. Although not shown, the polishing rate of barrier metal does not vary.

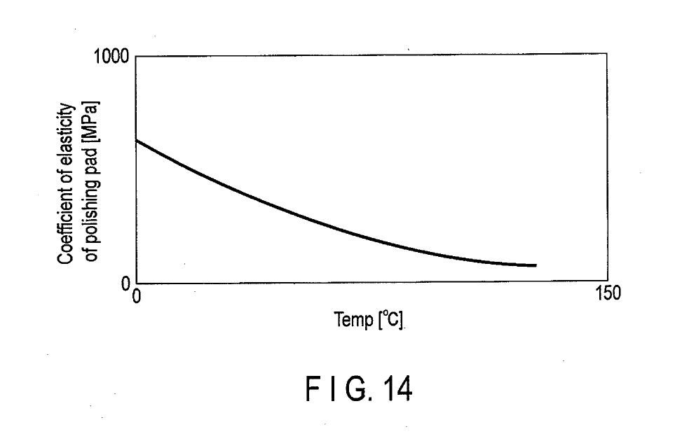

As shown in FIG. 14, the coefficient of elasticity of the polishing pad 41 depends on temperature. More specifically, the coefficient of elasticity of the polishing pad 41 decreases as the temperature thereof increases. As the coefficient of elasticity of the polishing pad 41 varies, the polishing characteristics also vary. That is, as the temperature of the surface of the polishing pad 41 varies, the polishing characteristics also vary. As a result, the polishing characteristics deteriorate.

In the present embodiment, on the other hand, from the first polishing process through the second polishing process, the temperature of the surface of the polishing pad 41 is controlled so as to be constant by adjusting the cooling nozzle 45 and the polishing load between the polishing pad 41 and the target film. This becomes possible by continuously performing the first polishing process and the second polishing process on the same table. That is, the first polishing process and the second polishing process are performed continuously, and a dresser process on the surface of the polishing pad 41 is not performed during the processes. Accordingly, the first polishing process and the second polishing process can be performed without varying the condition (temperature) of the surface of the polishing pad 41. Thereby, stable polishing characteristics are maintained from the first polishing process through the second polishing process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
forming an insulating film on a surface of a semiconductor substrate;
forming a groove in the insulating film;
forming an underlayer film on the insulating film;
forming a metal film on the underlayer film so as to fill in the groove;
performing first polishing, in which the metal film is removed from a portion other than the groove, by making the surface of the semiconductor substrate contact with a rotating polishing pad and supplying a first CMP slurry containing metal ions to a surface of the polishing pad;
cleaning the surface of the polishing pad and the semiconductor substrate by making the surface of the semiconductor substrate contact with the polishing pad and supplying organic acid and pure water to the surface of the polishing pad; and
performing second polishing, in which the underlayer film is removed from the portion other than the groove by making the surface of the semiconductor substrate contact with the polishing pad and supplying a second CMP slurry different from the first CMP slurry to the surface of the polishing pad.

2. The method of claim 1, wherein a temperature of the polishing pad is controlled from the first polishing through the second polishing.

3. The method of claim 2, wherein the temperature of the polishing pad is controlled so as to be constant.

4. The method of claim 3, wherein the temperature of the polishing pad ranges from 30 to 65° C.

5. The method of claim 1, wherein the organic acid forms a chelate compound with the metal ions.

6. The method of claim 5, wherein the organic acid includes one of citric acid and malic acid.

7. The method of claim 1, wherein the metal ions include one of Fe ions and Cu ions.

8. The method of claim 1, wherein a polishing rate of the second CMP slurry on the underlayer film is higher than a polishing rate of the first CMP slurry on the underlayer film.

9. The method of claim 1, wherein the metal film contains one of W and Cu.

10. The method of claim 1, wherein the underlayer film contains one of Ti and Ta, or a nitride thereof.

11. The method of claim 1, wherein the first polishing and the second polishing are performed in the same chamber.

12. A method of manufacturing a semiconductor device comprising:
forming an insulating film on a surface of a semiconductor substrate;
forming a groove in the insulating film;
forming an underlayer film on the insulating film;
forming a metal film on the underlayer film so as to fill in the groove;
performing first polishing, in which the metal film is removed from a portion other than the groove, by making the surface of the semiconductor substrate contact with a rotating polishing pad and supplying a first CMP slurry containing metal ions to a surface of the polishing pad; and
cleaning the surfaces of the polishing pad and the semiconductor substrate by making the surface of the semiconductor substrate contact with the polishing pad and supplying organic acid and pure water to the surface of the polishing pad, wherein
a temperature of the polishing pad is controlled in the first polishing.

13. The method of claim 12, wherein the temperature of the polishing pad is controlled so as to be constant.

14. The method of claim 13, wherein the temperature of the polishing pad ranges from 30 to 65° C.

15. The method of claim 11, wherein the organic acid forms a chelate compound with the metal ions.

16. The method of claim 15, wherein the organic acid includes one of citric acid and malic acid.

17. The method of claim 11, wherein the metal ions include one of Fe ions and Cu ions.

18. The method of claim 11, wherein a polishing rate of the second CMP slurry on the underlayer film is higher than a polishing rate of the first CMP slurry on the underlayer film.

19. The method of claim 11, wherein the metal film contains one of W and Cu.

20. The method of claim 11, wherein the underlayer film contains one of Ti and Ta, or a nitride thereof.
